(19) United States
(12) Patent Application Publication
(10) Pub. No.: US 2026/0269830 A1
(43) Pub. Date: Sep. 10, 2026

(54) INVERTER CIRCUIT WITH SUPPRESSED THRESHOLD VOLTAGE FROM VARYING WITH MANUFACTURING VARIATION, TEMPERATURE AND POWER SUPPLY VOLTAGE

(71) Applicant: NISSHINBO MICRO DEVICES INC., Tokyo (JP)

(72) Inventor: Shimpei Hidaka, Tokyo (JP)

(21) Appl. No.: 19/167,560

(22) PCT Filed: Apr. 19, 2023
(86) PCT No.: PCT/JP2023/015586

§ 371 Date: Sep. 22, 2025

(51) Int. Cl. H03K 19/00; H03K 19/20

(52) U.S. Cl. CPC H03K 19/0027; H03K 19/20

(57) ABSTRACT

An inverter circuit according to the present invention is configured to include a series circuit in which a first switch element and a load element are connected in series between two voltages that are different from each other. An input voltage inputted to an input terminal is inverted by the first switch element, and the inverted output voltage is outputted from an output terminal. The inverter circuit is provided with a current source for adjusting the current flowing through the first switch element, thereby adjusting an inverted threshold voltage of the inverter circuit. The current source adjusts the current flowing through the first switch element by allowing a prescribed adjustment current to flow into or out of the first switch element.

### TECHNICAL FIELD

The present invention relates to an inverter circuit that inverts a binary input voltage and outputs the inverted binary output voltage.

### BACKGROUND ART

There are many integrated circuits (hereinafter, referred to as “IC”) having a standby state for the purpose of reducing standby power when not operating in an electronic device. For the operation in the standby state, a method of controlling the standby state or the active enable state of the IC by inputting an activation signal voltage of the IC from the outside of the IC is used.

When this enable control circuit is mounted in an IC chip, it is required to configure the circuit that does not increase consumption current at the time of standby, and by adopting a comparator configuration using a threshold voltage of a single MOS field effect transistor (hereinafter, it is referred to as a “MOS transistor”, and a field effect transistor is referred to as “FET”), an enable control circuit of the IC can be configured simply and without increasing consumption current.

On the other hand, the voltage of the enable control signal is decreasing as ICs used in the periphery are miniaturized and lowered in voltage. When an FET having an ON-low-threshold voltage is simply used, the off-side threshold characteristics are excessively decreased in consideration of temperature characteristics and process variations. Therefore, there is a possibility that the enable control signal cannot be cut off by the control signal, and the threshold needs to be controlled with high accuracy including the temperature characteristics in order to realize the market demand. For this purpose, a method of configuring a comparator with a reference voltage having good temperature characteristics, a method of lowering an input transistor threshold by controlling a back gate of an input transistor, or the like has been already known (see, for example, Patent Documents 1 and 2).

### PRIOR ART DOCUMENTS

### Patent Documents

Patent Document 1: Japanese Patent No. JP4620522B2

Patent Document 2: Japanese Patent No. JP5181893B2

### SUMMARY OF THE INVENTION

### Problems to be Solved by the Invention

However, all the enable control circuits realized by the conventional circuit methods have trade-off characteristics. Since a comparator generated using a threshold of a single FET with a simple configuration fluctuates due to the influence of process variation in IC manufacturing, it is difficult to accurately control the threshold. In addition, the method of using a reference voltage having good temperature characteristics consumes a current for generating the reference voltage, so that the standby current increases.

In the method of controlling the back gate of the FET, in order to create a device capable of separating the back gate potential of the FET from the substrate, there is such a problem that an additional process step is included, which is disadvantageous in terms of cost and delivery, and a parasitic diode in a substrate voltage potential direction from the back gate potential easily flows the forward current, which is likely to lead to latch-up.

An object of the present disclosure is to solve the above problems and to provide an inverter circuit having a predetermined threshold without any additional step of separating a back gate potential from a substrate in manufacturing and without concern of latch-up.

### Solutions to Problems

According to one aspect of the present disclosure, there is provided an inverter circuit including a series circuit having a first switch element and a load element connected in series between two voltages different from each other. The inverter circuit inverts an input voltage inputted to an input terminal by the first switch element, and outputs an inverted output voltage from an output terminal. The inverter circuit further is configured to include a current source configured to adjust an inverted threshold voltage of the inverter circuit by adjusting a current flowing through the first switch element.

### Effects of the Invention

Therefore, according to the inverter circuit according to one aspect of the present disclosure, it is possible to provide the inverter circuit having a predetermined threshold without any additional step of separating the back gate potential from the substrate in manufacturing and without concern of latch-up. In particular, the inverted threshold voltage of the inverter circuit that outputs the binary signal can be suppressed from varying with manufacturing variation, temperature, power supply voltage, and the like.

### BRIEF DESCRIPTION OF THE DRAWINGS

FIG. 1 is a circuit diagram illustrating a configuration example of an inverter circuit according to a first embodiment.

FIG. 2 is a circuit diagram illustrating a configuration example of an inverter circuit according to a second embodiment.

FIG. 3 is a circuit diagram illustrating a configuration example of an inverter circuit according to a third embodiment.

FIG. 4 is a circuit diagram illustrating a configuration example of an inverter circuit according to a fourth embodiment.

FIG. 5 is a circuit diagram illustrating a configuration example of an inverter circuit according to a fifth embodiment.

FIG. 6 is a circuit diagram illustrating a configuration example of an inverter circuit according to a sixth embodiment.

FIG. 7 is a circuit diagram illustrating a configuration example of an inverter circuit according to a seventh embodiment.

FIG. 8 is a graph illustrating characteristics of a drain-source current Ids of an NMOS transistor and a threshold voltage Vth of an inverter circuit with respect to an input voltage Vin in an inverter circuit according to a conventional example.

FIG. 9 is a graph illustrating characteristics of a drain-source current Ids of a MOS transistor Q1 and a threshold voltage Vth of the inverter circuit with respect to an input voltage Vin in the inverter circuit according to the embodiments.

FIG. 10 is a graph illustrating temperature characteristics of a threshold voltage Vth of a general NMOS transistor.

FIG. 11 is a graph illustrating temperature characteristics of a threshold voltage Vth of an inverter circuit of a conventional example.

FIG. 12 is a circuit diagram illustrating a configuration example of an inverter circuit according to an eighth embodiment.

FIG. 13 is a graph illustrating temperature characteristics of a leakage current of a general NMOS transistor.

FIG. 14 is a graph illustrating temperature characteristics of a threshold voltage Vth of the inverter circuit according to the embodiments.

FIG. 15 is a circuit diagram illustrating a configuration example of an inverter circuit according to a ninth embodiment.

FIG. 16 is a graph illustrating characteristics of a threshold voltage depending on a power supply voltage of the inverter circuit according to each of the conventional example and the ninth embodiment.

FIG. 17A is a circuit diagram illustrating a configuration example of an inverter circuit according to a tenth embodiment.

FIG. 17B is a circuit diagram illustrating a configuration example of an inverter circuit according to a modified embodiment of the tenth embodiment.

FIG. 18 is a circuit diagram illustrating a configuration example of an inverter circuit according to an eleventh embodiment.

FIG. 19 is a circuit diagram illustrating a configuration of an inverter circuit according to Comparative Example 1.

FIG. 20 is a circuit diagram illustrating a configuration of an inverter circuit according to Comparative Example 2.

### DETAILED DESCRIPTION

Hereinafter, embodiments and modified embodiments according to the present invention will be described with reference to the drawings. It is noted that the same or similar components are denoted by the same reference signs.

First of all, findings of the inventor of the inverter circuits according to Comparative Examples 1 and 2 will be described below. In the present specification, an N-channel MOS transistor is referred to as an “NMOS transistor”, and a P-channel MOS transistor is referred to as a “PMOS transistor”.

### FINDINGS OF INVENTOR

### COMPARATIVE EXAMPLE 1

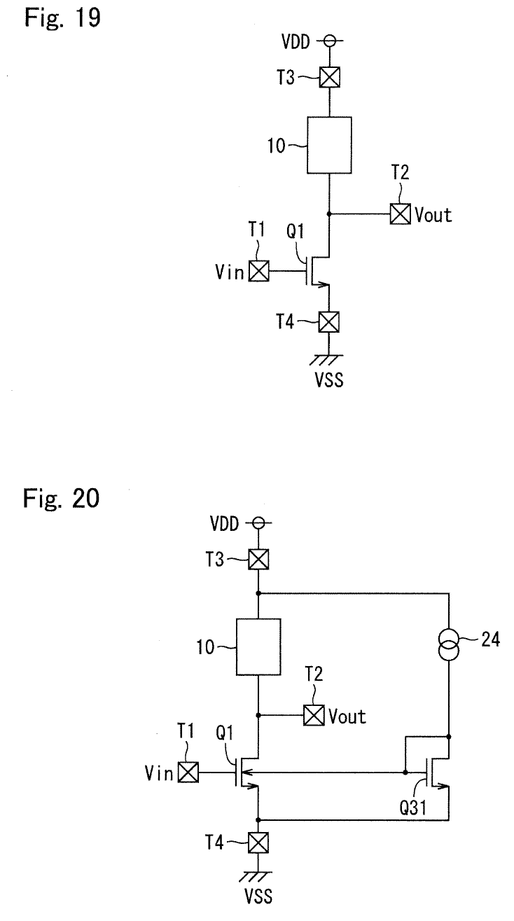

FIG. 19 is a circuit diagram illustrating a configuration of an inverter circuit according to Comparative Example 1.

Referring to FIG. 19, the inverter circuit according to Comparative Example 1 is configured to include an input terminal T1, an output terminal T2, a power supply terminal T3, and a ground terminal T4, and is configured to include an NMOS transistor Q1 and a load element 10. In this case, the load element 10 is configured to include, for example, an FET, a resistor, or the like. The power supply voltage VDD is connected to the power supply terminal T3, and the ground terminal T4 is grounded to become the ground voltage VSS.

In the inverter circuit of FIG. 19, when the low-level input voltage Vin, which is the ground voltage VSS, is inputted to the input terminal T1, a NMOS transistor Q1 is turned off, and the high-level output voltage Vout, which is the power supply voltage VDD, is outputted from the output terminal T2. In this case, when the input voltage Vin changes from the low level to the high level, that is, changes from the ground voltage VSS to the power supply voltage VDD, the NMOS transistor Q1 is turned on, and the low-level output voltage Vout is outputted from the output terminal T2.

In the inverter circuit configured as described above, the operation threshold voltage Vth of the inverter circuit can be set by appropriately setting the NMOS transistor Q1 and the resistance values of the load element 10. At this time, the threshold voltage Vth of the NMOS transistor Q1 depends on the manufacturing process, and the threshold voltage Vth varies depending on manufacturing variations. The threshold voltage Vth also varies depending on the temperature of the NMOS transistor Q1.

### COMPARATIVE EXAMPLE 2

FIG. 20 is a circuit diagram illustrating a configuration of an inverter circuit according to Comparative Example 2.

The inverter circuit of FIG. 20 is an example in which the conventional art described in in the section of BACKGROUND ART is applied to the inverter circuit, and is configured to include the input terminal T1, the output terminal T2, the power supply terminal T3, and the ground terminal T4, and to further include the NMOS transistor Q1, the load element 10, a constant current source 24, and an NMOS transistor Q31. In this case, a bias voltage generated by allowing a current to flow through a node of saturation connection of the NMOS transistor Q31 having the same electrical characteristics as that of the input transistor is applied to a back gate of the NMOS transistor Q1 which is an input transistor.

In the inverter circuit configured as described above, the NMOS transistor Q1 and the NMOS transistor Q31 are devices of the same characteristic. The threshold voltage Vth of the NMOS transistor Q1 varies is compatible to the threshold voltage Vth of the NMOS transistor Q31 varies. That is, in the wafer manufactured such that the threshold voltage Vth of the NMOS transistor Q1 increases, the threshold voltage Vth of the NMOS transistor Q31 for back gate bias generation also increases, the back gate bias voltage generated by the NMOS transistor Q31 also increases, and the back gate effect increases, so that the threshold voltage Vth of the NMOS transistor Q1 further decreases. As a result, a back gate bias that suppresses variations in manufacturing is generated.

However, as described in the section of PROBLEMS TO BE SOLVED BY THE INVENTION, in this circuit configuration, it is necessary to add a manufacturing process for separating the back gate of the NMOS transistor Q1 of the input transistor from the substrate voltage potential. In addition, when the back gate bias voltage generated by the NMOS transistor Q31 and the constant current source 24 is too high, there is a concern that the parasitic diode in the direction from the back gate to the source is turned on, so that latch-up is likely to occur.

An object of the following embodiment according to the present invention is to solve the above problems and to provide an inverter circuit having a predetermined threshold without any additional step of separating a back gate potential from a substrate in manufacturing and without concern of latch-up.

### First Embodiment

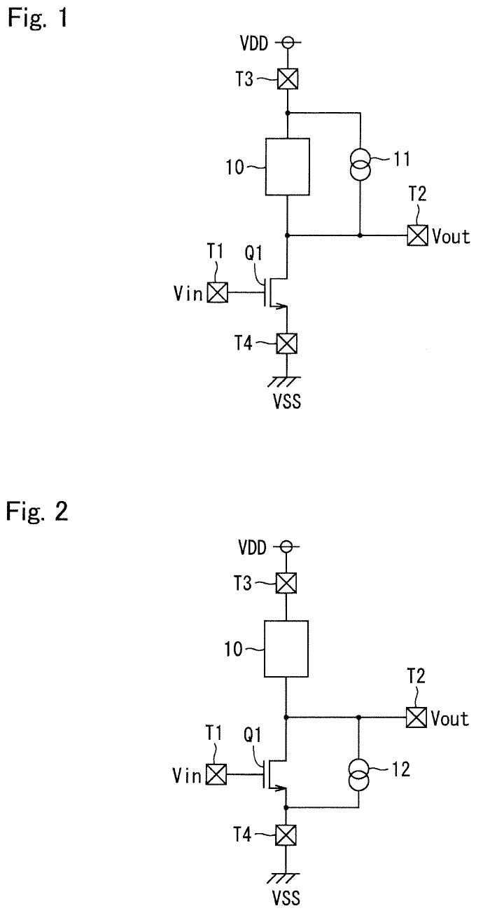

FIG. 1 is a circuit diagram illustrating a configuration example of an inverter circuit according to a first embodiment.

Referring to FIG. 1, the inverter circuit according to the first embodiment is configured to include the input terminal T1, the output terminal T2, the power supply terminal T3, and the ground terminal T4, and to further include the NMOS transistor Q1, the load element 10, and a constant current source 11. In this case, the load element 10 is configured to include, for example, an FET, a resistor, or the like. The power supply voltage VDD is connected to the power supply terminal T3, and the ground terminal T4 is grounded to become the ground voltage VSS. In FIG. 1, a series circuit of the NMOS transistor Q1 and the load element 10 is connected between the power supply terminal T3 and the ground terminal T4, and the constant current source 11 is connected in parallel to the load element 10.

In the inverter circuit configured as described above, when the low-level input voltage Vin, which is the ground voltage VSS, is inputted to the input terminal Tl, the NMOS transistor Q1 is turned off. Then, the high-level output voltage Vout, which is the power supply voltage VDD, is outputted from the output terminal T2. In this case, when the input voltage Vin changes from the low level to the high level, that is, changes from the ground voltage VSS to the power supply voltage VDD, the NMOS transistor Q1 is turned on, and the low-level output voltage Vout is outputted from the output terminal T2.

Furthermore, in the inverter circuit of FIG. 1, the constant current source 11 operates so as to add (add in) the current flowing through the NMOS transistor Q1 by the constant current amount (adjustment current) of the constant current source 11, that is, operates to allow the constant current amount to flow, and the voltage of the input voltage Vin required for determining the polarity of the output terminal T2 changes so as to increase by the current amount to be added to the NMOS transistor Q1. Therefore, the inverted threshold voltage Vth of the inverter circuit is controlled by adjusting the current amount. Therefore, it is possible to provide an inverter circuit having a predetermined threshold without any additional step of separating the back gate potential from the substrate in manufacturing and without concern of latch-up

### Second Embodiment

FIG. 2 is a circuit diagram illustrating a configuration example of an inverter circuit according to a second embodiment.

Referring to FIG. 2, the inverter circuit according to the second embodiment is different from the inverter circuit according to the first embodiment in FIG. 1 in the following points.

(1) A constant current source 12 is provided instead of the constant current source 11. In this case, the constant current source 12 is connected in parallel with the source and the drain of the NMOS transistor Q1.

In the inverter circuit configured as described above, when the low-level input voltage Vin, which is the ground voltage VSS, is inputted to the input terminal T1, the NMOS transistor Q1 is turned off, and the high-level output voltage Vout, which is the power supply voltage VDD, is outputted from the output terminal T2. In this case, when the input voltage Vin changes from the low level to the high level, that is, changes from the ground voltage VSS to the power supply voltage VDD, the NMOS transistor Q1 is turned on, and then, the low-level output voltage Vout is outputted from the output terminal T2.

Furthermore, in the inverter circuit of FIG. 2, the constant current source 12 operates to subtract (draw out) a constant current amount (adjustment current) of the constant current source 12 from the current flowing through the NMOS transistor Q1, that is, operates to allow the constant current amount to flow out, and the voltage of the input voltage Vin required for determining the polarity of the output terminal T2 changes so as to decrease by the current amount subtracted from the NMOS transistor Q1. Therefore, the inverted threshold voltage Vth of the inverter circuit is controlled by adjusting the current amount. Therefore, it is possible to provide an inverter circuit having a predetermined threshold without any additional step of separating the back gate potential from the substrate in manufacturing and without concern of latch-up.

### Third Embodiment

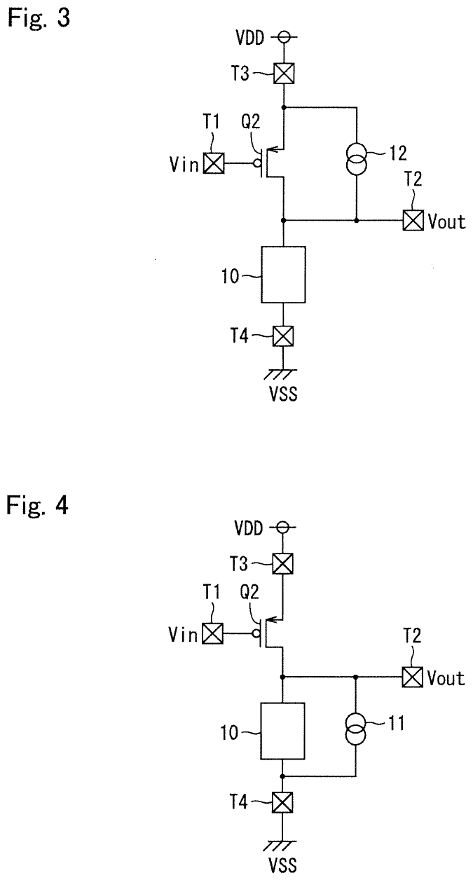

FIG. 3 is a circuit diagram illustrating a configuration example of an inverter circuit according to a third embodiment.

Referring to FIG. 3, the inverter circuit according to the third embodiment is configured to include the input terminal T1, the output terminal T2, the power supply terminal T3, and the ground terminal T4, and to further include a PMOS transistor Q2, the load element 10, and the constant current source 12. In this case, the load element 10 is configured to include, for example, an FET, a resistor, or the like. The power supply voltage VDD is connected to the power supply terminal T3, and the ground terminal T4 is grounded to become the ground voltage VSS. In FIG. 3, a series circuit of the PMOS transistor Q2 and the load element 10 is connected between the power supply terminal T3 and the ground terminal T4, and the constant current source 12 is connected in parallel to the source and the drain of the PMOS transistor Q2.

In the inverter circuit configured as described above, when the low-level input voltage Vin, which is the ground voltage VSS, is inputted to the input terminal T1, the PMOS transistor Q2 is turned on, then the high-level output voltage Vout, which is the power supply voltage VDD, is outputted from the output terminal T2. In this case, when the input voltage Vin changes from the low level to the high level, that is, changes from the ground voltage VSS to the power supply voltage VDD, the PMOS transistor Q2 is turned off, and then, the low-level output voltage Vout is outputted from the output terminal T2.

Furthermore, in the inverter circuit of FIG. 3, the constant current source 12 operates so as to subtract (draw out) the constant current amount (adjustment current) of the constant current source 12 from the current flowing through the PMOS transistor Q2, and the voltage of the input voltage Vin required for determining the polarity of the output terminal T2 changes so as to increase by the current amount subtracted from the PMOS transistor Q2. Therefore, the inverted threshold voltage Vth of the inverter circuit is controlled by adjusting the current amount. Therefore, it is possible to provide an inverter circuit having a predetermined threshold without any additional step of separating the back gate potential from the substrate in manufacturing and without concern of latch-up.

### Fourth Embodiment

FIG. 4 is a circuit diagram illustrating a configuration example of an inverter circuit according to a fourth embodiment.

Referring to FIG. 4, the inverter circuit according to the fourth embodiment is different from the inverter circuit according to the third embodiment in FIG. 3 in the following points.

(1) The constant current source 11 is provided instead of the constant current source 12. In this case, the constant current source 11 is connected in parallel with the load element 10.

In the inverter circuit configured as described above, when the low-level input voltage Vin, which is the ground voltage VSS, is inputted to the input terminal T1, the PMOS transistor Q2 is turned on, and the high-level output voltage Vout, which is the power supply voltage VDD, is outputted from the output terminal T2. In this case, when the input voltage Vin changes from the low level to the high level, that is, changes from the ground voltage VSS to the power supply voltage VDD, the PMOS transistor Q2 is turned off, and then, the low-level output voltage Vout is outputted from the output terminal T2.

Furthermore, in the inverter circuit of FIG. 4, the constant current source 11 operates so as to add the current flowing through the PMOS transistor Q2 by the constant current (adjustment current) of the constant current source 11, and the voltage of the input voltage Vin required for determining the polarity of the output terminal T2 changes so as to decrease by the amount of current to be added to the PMOS transistor Q2. Therefore, by adjusting the amount of current, the inverted threshold voltage Vth of the inverter circuit is controlled. Therefore, it is possible to provide an inverter circuit having a predetermined threshold without any additional step of separating the back gate potential from the substrate in manufacturing and without concern of latch-up.

As described above, in the first to fourth embodiments, the inverted threshold voltage Vth of the inverter circuit can be controlled by performing adjustment so as to add a predetermined adjustment current to the current flowing through the NMOS transistor Q1 or the PMOS transistor Q2 (first switch element) or subtract a predetermined adjustment current from the current flowing through the NMOS transistor Q1 or the PMOS transistor Q2. Therefore, it is possible to provide an inverter circuit having a predetermined threshold without any additional step of separating the back gate potential from the substrate in manufacturing and without concern of latch-up.

### Fifth Embodiment

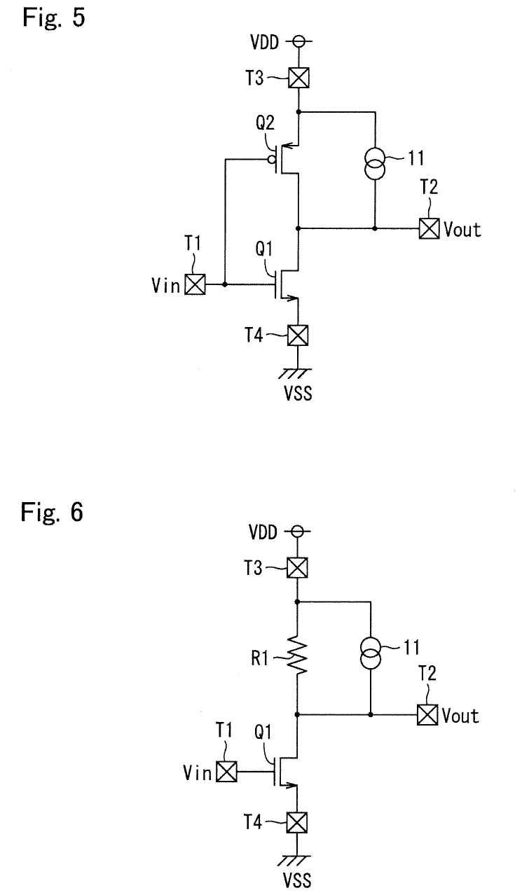

FIG. 5 is a circuit diagram illustrating a configuration example of an inverter circuit according to a fifth embodiment. The inverter circuit according to the fifth embodiment in FIG. 5 is different from the inverter circuit in FIG. 1 in the following points.

(1) The PMOS transistor Q2 is used as a specific element of the load element 10. In this case, the source of the PMOS transistor Q2 is connected to the power supply terminal T3, and the drain of the PMOS transistor Q2 is connected to the output terminal T2. The gate of the PMOS transistor Q2 is connected to the input terminal T1.

In the inverter circuit configured as described above, when the low-level input voltage Vin, which is the ground voltage VSS, is inputted to the input terminal T1, the NMOS transistor Q1 is turned off and the PMOS transistor Q2 is turned on, and the high-level output voltage Vout, which is the power supply voltage VDD, is outputted from the output terminal T2. In this case, when the input voltage Vin changes from the low level to the high level, that is, changes from the ground voltage VSS to the power supply voltage VDD, the NMOS transistor Q1 is turned on and the PMOS transistor Q2 is turned off, and then, the low-level output voltage Vout is outputted from the output terminal T2. Therefore, the inverter circuit according to the fifth embodiment has the same action and effect as those of the first embodiment.

### Sixth Embodiment

FIG. 6 is a circuit diagram illustrating a configuration example of an inverter circuit according to a sixth embodiment. The inverter circuit according to the sixth embodiment in FIG. 6 is different from the inverter circuit in FIG. 1 in the following points.

(1) As a specific element of the load element 10, a resistor R1 is used. In this case, one end of the resistor R1 is connected to the power supply terminal T3, and the other end of the resistor R1 is connected to the output terminal T2.

In the inverter circuit configured as described above, when the low-level input voltage Vin, which is the ground voltage VSS, is inputted to the input terminal T1, the NMOS transistor Q1 is turned off, and then, the high-level output voltage Vout, which is the power supply voltage VDD, is outputted from the output terminal T2. In this case, when the input voltage Vin changes from the low level to the high level, that is, changes from the ground voltage VSS to the power supply voltage VDD, the NMOS transistor Q1 is turned on, and the low-level output voltage Vout is outputted from the output terminal T2. Therefore, the inverter circuit according to the sixth embodiment has the same action and effect as those of the first embodiment.

### Seventh Embodiment

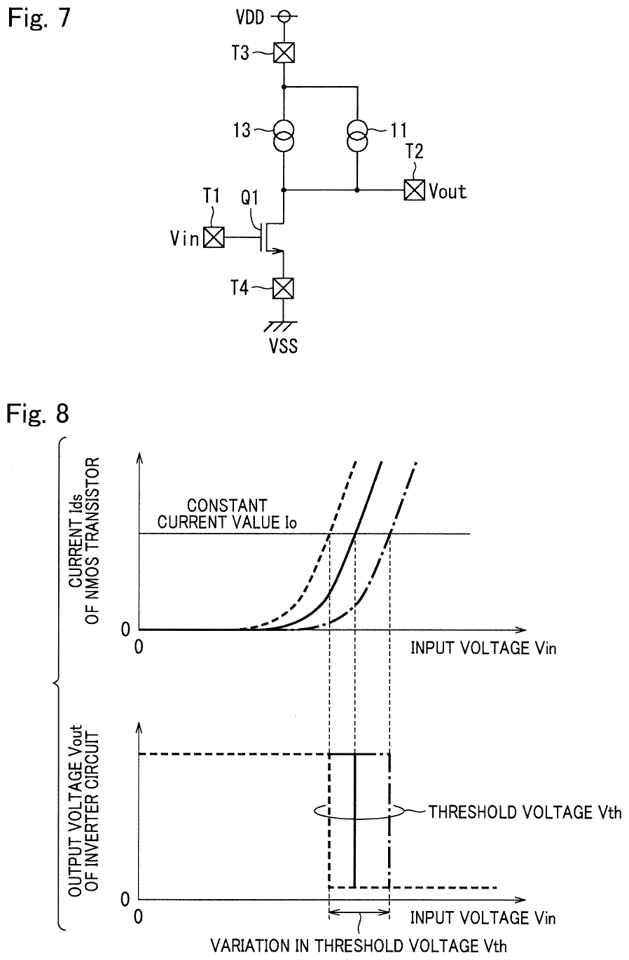

FIG. 7 is a circuit diagram illustrating a configuration example of an inverter circuit according to a seventh embodiment. The inverter circuit according to the seventh embodiment in FIG. 7 is different from the inverter circuit in FIG. 1 in the following points.

(1) A constant current source 13 is used as a specific element of the load element 10. In this case, one end of the constant current source 13 is connected to the power supply terminal T3, and the other end of the constant current source 13 is connected to the output terminal T2.

In the inverter circuit configured as described above, when the low-level input voltage Vin, which is the ground voltage VSS, is inputted to the input terminal T1, the NMOS transistor Q1 is turned off, and the high-level output voltage Vout, which is the power supply voltage VDD, is outputted from the output terminal T2. In this case, when the input voltage Vin changes from the low level to the high level, that is, changes from the ground voltage VSS to the power supply voltage VDD, the NMOS transistor Q1 is turned on, and then, the low-level output voltage Vout is outputted from the output terminal T2. Therefore, the inverter circuit according to the seventh embodiment has the same action and effect as those of the first embodiment.

### MODIFIED EMBODIMENTS

In the inverter circuit according to the second embodiment of FIG. 2, the resistor R1 of FIG. 6 or the constant current source 13 of FIG. 7 may be used as a specific element of the load element 10. Furthermore, in the inverter circuit according to the third or fourth embodiment of FIG. 3 or FIG. 4, as a specific element of the load element 10, the NMOS transistor Q1 instead of the PMOS transistor Q2 of FIG. 5, the resistor R1 of FIG. 6, or the constant current source 13 of FIG. 7 may be used.

### Variation in Threshold Voltage

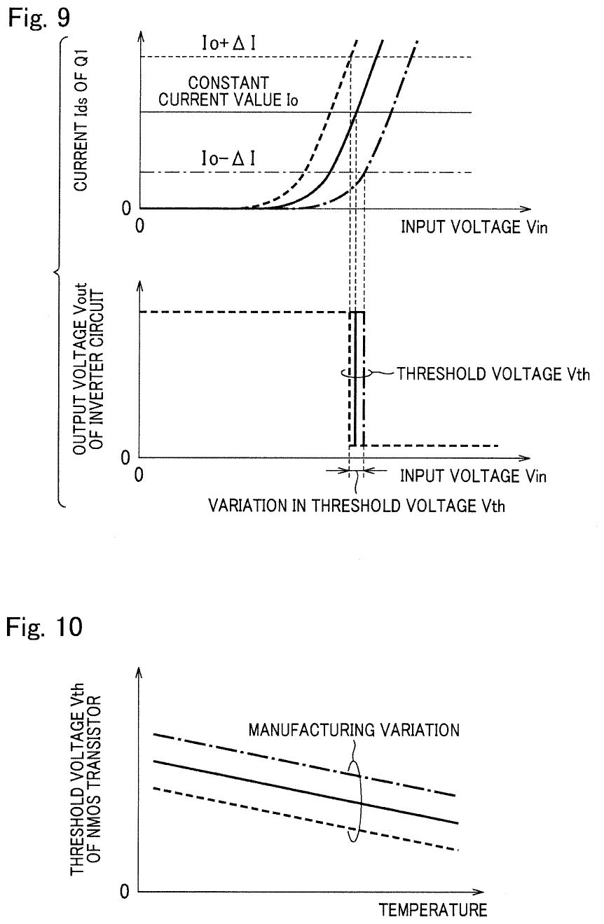

FIG. 8 is a graph illustrating characteristics of a drain-source current Ids of the NMOS transistor and an inverted threshold voltage Vth of the inverter circuit with respect to the input voltage Vin in the inverter circuit according to the conventional example (FIG. 19). FIG. 9 is a graph illustrating characteristics of the drain-source current Ids of the NMOS transistor Q1 and the inverted threshold voltage Vth of the inverter circuit with respect to the input voltage Vin in the inverter circuit according to the embodiment.

In this case, assuming that the load element 10 is the constant current source 13 illustrated in the seventh embodiment (FIG. 7) for the sake of simplicity, the inverter circuit performs an operation in which the output voltage thereof is inverted at the intersection of the characteristic curve of Ids vs. Vin of the NMOS transistor of FIG. 8 and the constant current value Io which is the current value of the constant current source 13. In the characteristic curve of Ids vs. Vin of the NMOS transistor, the input voltage Vin at which the current starts to flow as Ids changes depending on the threshold voltage Vth of the NMOS transistor. That is, even if the characteristics indicated by the solid line in FIG. 8 are designed as the center value, the characteristic curve changes as indicated by a broken line or an alternate long and short dash line due to manufacturing variations and temperature characteristics, and as a result, variations in the threshold voltage Vth are affected.

On the other hand, in the proposed inverter circuit according to the first to seventh embodiments, as illustrated in FIG. 9, in addition to the constant current value Io, by adding or subtracting the current amount (adjustment current) of the constant current sources 11 and 12 reflecting the characteristic fluctuation of the threshold voltage Vth of the input transistor, it is possible to control the change in the voltage at the intersection of the characteristic curve of the drain-source current Ids-Vin of the NMOS transistor Q1 and the total current value (Io+AI, Io-AI) of the constant current sources 11 and 12 to be reduced, and as a result, the variation in the inverted threshold voltage Vth of the inverter circuit is reduced. The adjustment current value of addition or subtraction is adjusted to a current having electrical characteristics according to an element (for example, power supply voltage VDD, temperature, or manufacturing variations) in which variation is desired to be reduced.

FIG. 10 is a graph illustrating temperature characteristics of the threshold voltage Vth of a general FET, and is a graph for describing temperature characteristics and manufacturing variations of the threshold voltage Vth of an NMOS transistor. In general, as characteristics of the NMOS transistor, the threshold voltage Vth decreases with respect to the temperature as illustrated in FIG. 10. In addition, as indicated by a broken line and an alternate long and short dash line in FIG. 10, the threshold voltage fluctuates due to the influence of manufacturing variation.

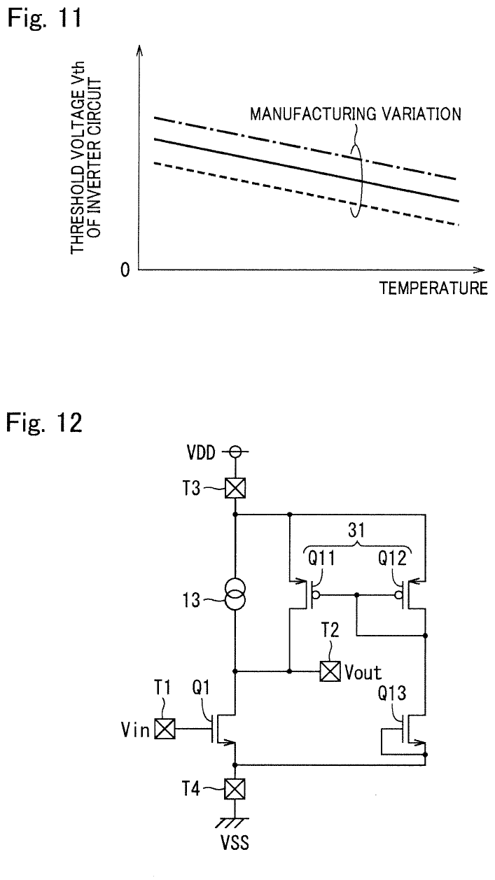

FIG. 11 is a graph illustrating temperature characteristics of the inverted threshold voltage Vth of the inverter circuit of the conventional example (FIG. 19). As is clear from the temperature characteristics of FIG. 10, for example, since the threshold voltage Vth characteristics of the NMOS transistor Q1 of FIG. 19 are affected by the temperature characteristics or manufacturing variations, the inverted threshold voltage Vth of the inverter circuit of FIG. 19 also changes according to the characteristics.

### Eighth Embodiment

FIG. 12 is a circuit diagram illustrating a configuration example of an inverter circuit according to an eighth embodiment. The inverter circuit of FIG. 12 is different from the inverter circuit of FIG. 7 in the following points.

(1) Instead of the constant current source 11, a current mirror circuit 31 including PMOS transistors Q11 and Q12 and configured as a variable current source, and an NMOS transistor Q13 whose gate and source are connected to each other are provided.

Differences will be described below.

Referring to FIG. 12, the source and the drain of the PMOS transistor Q11 are connected in parallel to the constant current source 13, and the gate of the PMOS transistor Q11 is connected to the gate of the PMOS transistor Q12. The gate and the drain of the PMOS transistor Q12 and the drain of the NMOS transistor Q13 are connected to each other. Furthermore, the gate and the source of the NMOS transistor Q13 are connected to the terminal T4 and grounded.

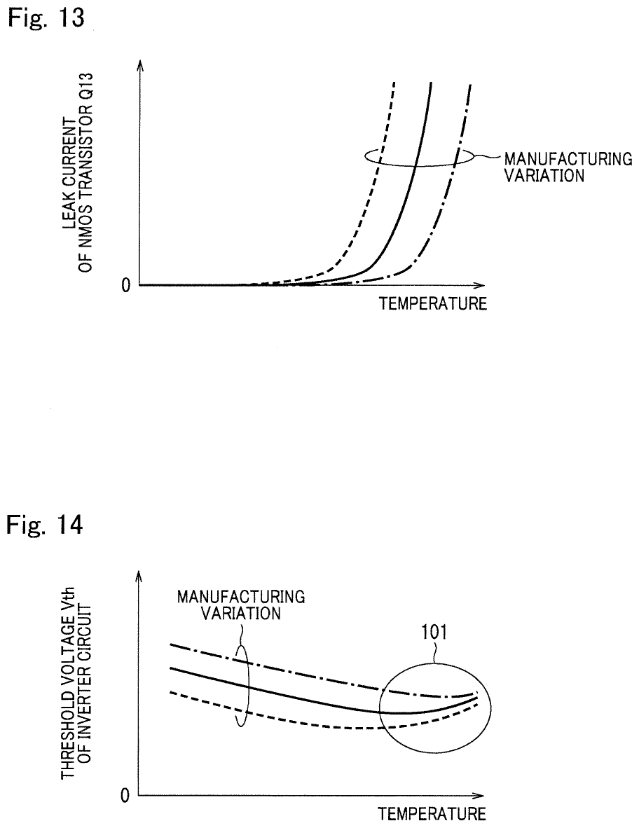

In the inverter circuit configured as described above, the PMOS transistor Q12 and the NMOS transistor Q13 are configured as a constant current source that allows a predetermined current to flow, and the current corresponding to the current caused by the constant current source flows into the NMOS transistor Q1. That is, the leakage current at a high temperature of the NMOS transistor Q13 is folded back at the PMOS transistors Q11 and Q12, and the leakage current flows into the drain of the NMOS transistor Q1. In this case, since the leakage current of the NMOS transistor Q13, which is a semiconductor element, has characteristics of rapidly increasing only at a high temperature as illustrated in FIG. 13, no current flows through the NMOS transistor Q13 and the PMOS transistors Q11 and Q12 in a low temperature region. As a result, the added current (adjustment current) is adjusted such that the inverted threshold voltage Vth of the inverter circuit becomes high only at a high temperature, and cancels out the threshold voltage Vth characteristics that are negative characteristics with respect to the temperature of the MOS transistor, and the temperature dependence of the inverted threshold voltage of the inverter circuit is suppressed.

As an advantage of the above circuit configuration, since the correction by the leakage current is performed only at a high temperature, it is possible to control the inverted threshold voltage of the inverter circuit at a normal temperature without increasing the consumption current of the circuit. At this time, the NMOS transistor Q1 and the NMOS transistor Q13 do not need to be devices having the same size and the same threshold voltage Vth, and the desired threshold voltage can be corrected by changing the leakage current characteristics according to the threshold voltage Vth to be adjusted.

In addition, although the NMOS transistor Q13 has a gate and a source connected to each other, the gate voltage for turning off the NMOS transistor Q13 may be applied at room temperature, and the gate voltage may be adjusted to a gate voltage having characteristics that a leakage current appears at a high temperature higher than a predetermined threshold temperature, for example.

As described above, according to the eighth embodiment, the adjustment current adjusted to exhibit the desired threshold voltage characteristics is added to the output terminal T2 of the inverter circuit, and the threshold adjustment using the back gate effect is not used.

FIG. 13 is a graph illustrating temperature characteristics of a leakage current of a general NMOS transistor, and a broken line and an alternate long and short dash line indicate that the temperature at which the leakage current characteristics start to occur is high or low due to manufacturing variations of the threshold voltage Vth of the NMOS transistor. That is, in the NMOS transistor, the NMOS transistor made such that the threshold voltage Vth becomes high does not generate a leakage current up to a higher temperature as indicated by an alternate long and short dash line, whereas the NMOS transistor made such that the threshold voltage Vth becomes low has leakage current characteristics of generating a leakage current at a lower temperature as indicated by a dotted line.

FIG. 14 is a graph illustrating temperature characteristics of the inverted threshold voltage Vth of the inverter circuit according to the embodiment. By setting the NMOS transistor Q13 in FIG. 12 having the leakage current characteristics in the off-state in FIG. 13 and the NMOS transistor Q1 having the threshold voltage Vth characteristics in FIG. 13 to a predetermined optimum design ratio, for example, it is possible to suppress a decrease in the threshold voltage Vth at a high temperature higher than a predetermined threshold temperature that is normal temperature, and to make the lower limit value of the threshold voltage Vth higher than that in the conventional technique as illustrated in FIG. 14. Further, in the circuit configuration, the leakage current of the NMOS transistor Q13 is generated at a relatively low temperature for the manufacturing variations in which the threshold voltage Vth of the NMOS transistor Q1 is low, and the leakage current starts to be generated from a relatively high temperature for the manufacturing variations in which the threshold voltage Vth is high. Therefore, the fluctuation range of the threshold voltage including the manufacturing variations and the temperature characteristics is suppressed.

By using the inverter circuit according to the eighth embodiment of FIG. 12, for example, even when the NMOS transistor Q1 tuned to have a low threshold voltage Vth as an absolute value is used for the input terminal T1, it is possible to realize characteristics that prevent the NMOS transistor Q1 from being cut off by the control signal even if temperature characteristics or manufacturing variations are included, and it is possible to configure the inverter circuit with a low threshold voltage Vth.

### Ninth Embodiment

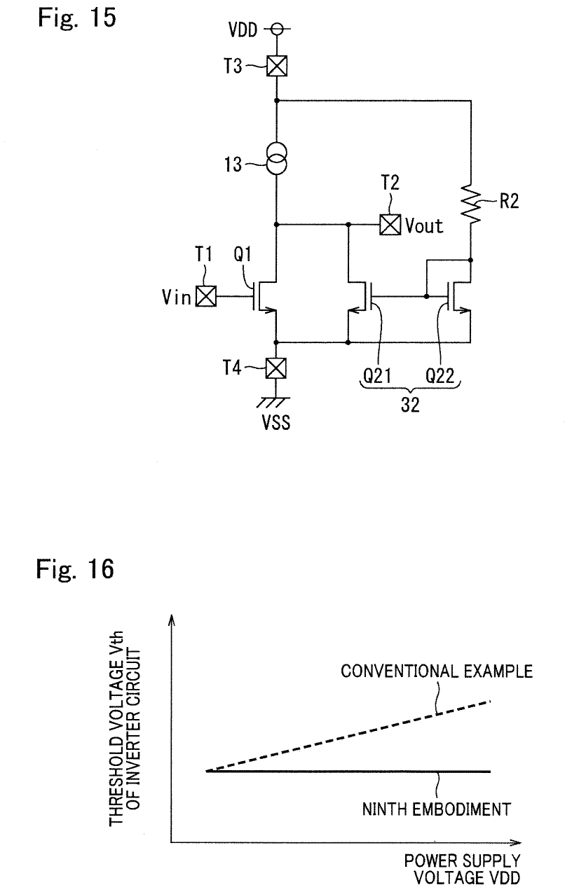

FIG. 15 is a circuit diagram illustrating a configuration example of an inverter circuit according to a ninth embodiment. The inverter circuit of FIG. 15 is different from the inverter circuit of FIG. 7 in the following points.

(1) Instead of the constant current source 11, a current mirror circuit 32 including NMOS transistors Q21 and Q22 and configured as a variable current source, and a resistor R2 are provided.

Differences will be described below.

Referring to FIG. 15, the drain and the source of the NMOS transistor Q21 are connected in parallel to the drain and the source of the NMOS transistor Q1, and the gate of the NMOS transistor Q21 is connected to the gate of the NMOS transistor Q22. The gate and the drain of the NMOS transistor Q22 are connected to one end of the resistor R2, and the other end of the resistor R2 is connected to a power supply terminal T3. Further, the sources of the NMOS transistors Q21 and Q22 are connected to the terminal T4 and grounded.

The inverter circuit configured as described above is an example of a circuit that improves the fluctuation of the threshold voltage Vth depending on the power supply voltage VDD. In this case, the current flowing through the NMOS transistor Q22 and the resistor R2 is a function of the power supply voltage VDD and the resistance value of the resistor R2, and the end-to-end voltage applied to the resistor R2 changes to be large and small in accordance with the vertical fluctuation of the power supply voltage VDD, and the current is also generated in proportion. Since a current proportional to the power supply voltage VDD flows through the NMOS transistor Q22 and a current corresponding to the flowing current flows through the NMOS transistor Q21, the adjustment current proportional to the power supply voltage VDD is drawn out from the current flowing through the NMOS transistor Q1 of the inverter circuit so as to be subtracted.

FIG. 16 is a graph illustrating characteristics of a threshold voltage depending on the power supply voltage of the inverter circuit according to each of the conventional example and the ninth embodiment.

As illustrated in FIG. 16, in the inverter circuit according to the conventional example, in a case where the short channel effect of the NMOS transistor which is an input transistor becomes apparent and the threshold voltage Vth also increases with respect to the power supply voltage VDD, the fluctuation range can be appropriately adjusted by using the circuit configuration according to the ninth embodiment. On the other hand, when the short channel effect of the NMOS transistor Q1 as an input transistor becomes apparent and the threshold voltage Vth decreases with respect to the power supply voltage VDD, the polarity of the NMOS transistors Q21 and Q22 is switched, the current mirror circuit 32 is configured by the NMOS transistors Q21 and Q22 whose sources are connected to the power supply voltage VDD, and a current may be injected into the NMOS transistor Q1 so as to increase the threshold voltage Vth by adding a predetermined adjustment current.

As described above, in the circuit configuration of the conventional example, it is assumed that the threshold voltage Vth has a positive correlation with the power supply voltage as indicated by the broken line in FIG. 16, and the solid line in FIG. 16 is adjusted by the correction function of the inverter circuit according to the present embodiment 9 so that the threshold voltage Vth is constant with respect to the power supply voltage VDD.

### Tenth Embodiment

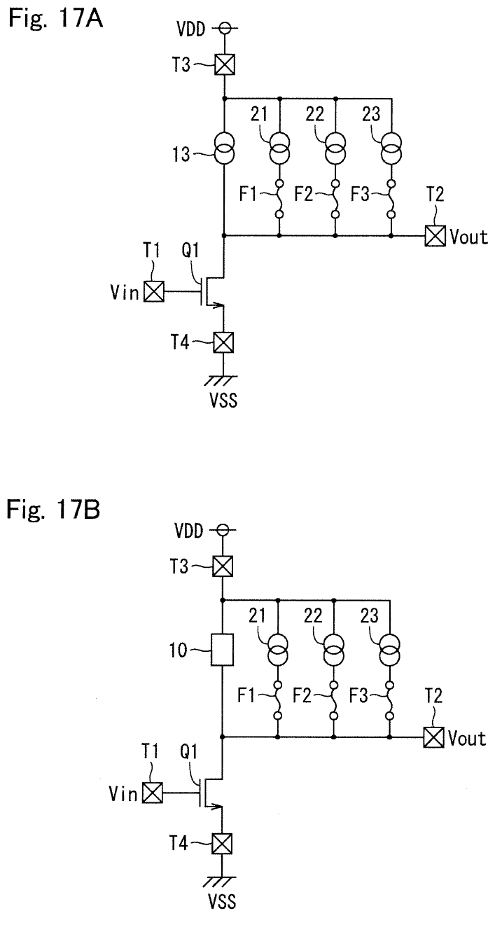

FIG. 17A is a circuit diagram illustrating a configuration example of an inverter circuit according to a tenth embodiment. The inverter circuit of FIG. 17A is different from the inverter circuit according to the seventh embodiment of FIG. 7 in the following points.

(1) Instead of the constant current source 11, there is provided a parallel circuit of
(A) a series circuit of a constant current source 21 and a trimming fuse F1;
(B) a series circuit of a constant current source 22 and a trimming fuse F2; and
(C) a series circuit of a constant current source 23 and a trimming fuse F3.

Differences will be described below.

Referring to FIG. 17A, the amount of current to be added to the constant current source 13 (adjustment current) can be adjusted by keeping the trimming fuses F1 to F3 on as they are or by cutting off at least one of the trimming fuses F1 to F3.

As a result, the inverted threshold voltage Vth of the inverter circuit can be adjusted.

In FIG. 17A, three series circuits of the constant current sources 21 to 23 and the trimming fuses F1 to F3 are provided, but the present invention is not limited thereto, and one or more series circuits may be provided. In addition, as illustrated in FIG. 17B according to the modified embodiment, the current source 13 may be various load elements 10 such as resistors or MOS transistors.

### Eleventh Embodiment

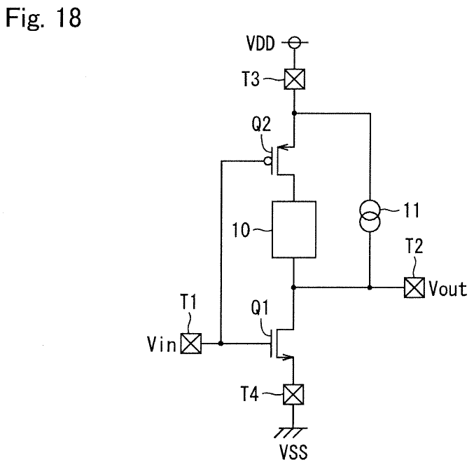

FIG. 18 is a circuit diagram illustrating a configuration example of an inverter circuit according to an eleventh embodiment. The inverter circuit according to the eleventh embodiment of FIG. 18 is different from the inverter circuit of FIG. 1 in the following points.

(1) The PMOS transistor Q2 is inserted between the power supply terminal T3 and the load element 10. That is, a CMOS circuit is configured to include the PMOS transistor Q2 having complementarity with the NMOS transistor Q1 as an input transistor.

Differences will be described below.

Referring to FIG. 18, the power supply terminal T3 is connected to one end of the constant current source 11 and is connected to the source of the PMOS transistor Q2. The drain of the PMOS transistor Q2 is connected to one end of the load element 10. The gate of the PMOS transistor Q2 is connected to the input terminal T1.

According to the inverter circuit configured as described above, as described with reference to FIG. 1, the threshold voltage Vth of the inverted threshold of the inverter circuit is determined by the ON characteristics of the NMOS transistor Q1.

According to the present embodiment, the inverted threshold voltage Vth of the inverter circuit can be adjusted by adding or subtracting the adjustment current adjusted by the constant current source 11 or the constant current source 12 to or from the input voltage Vin near the threshold voltage Vth. Therefore, for the input voltage Vin outside the range to be adjusted, specifically, for the input voltage Vin sufficiently higher than the threshold voltage Vth in the circuit configuration of FIG. 1 or FIG. 18, the output terminal T2 is sufficiently pulled down by the capability of the NMOS transistor Q1, and it is determined to output the low-level output voltage Vout having the ground voltage VSS, so that the threshold voltage does not need to be corrected by the effect of the invention.

Therefore, as illustrated in FIG. 18, the PMOS transistor Q2 that cuts off the current flowing through the inverter circuit in the range of the input voltage Vin that does not affect the characteristics of the adjustment threshold voltage Vth, specifically, in a case where the input voltage Vin is close to the power supply voltage VDD is inserted in series to the NMOS transistor Q1, so that the through current of the inverter circuit can be reduced. In addition, by connecting the adjusted current source to the drain terminal of the PMOS transistor Q2 instead of the source of the PMOS transistor Q2, the consumption current due to the addition of the adjustment current can also be reduced.

As illustrated in FIG. 18, in order to reduce the consumption current with respect to the input voltage Vin in a range not affecting the threshold characteristics, the current flowing through the NMOS transistor Q1 as the input transistor may be cut off using the PMOS transistor Q2 having complementarity. In this case, if the input transistor is a PMOS transistor, an NMOS transistor may be used for blocking.

Furthermore, in the description of the inverter circuit according to the eleventh embodiment of FIG. 18, the inverter circuit having the threshold voltage Vth with reference to the ground voltage VSS has been described, but the present invention is not limited thereto. In a case where the threshold voltage Vth with reference to the power supply voltage VDD is adjusted, a PMOS transistor may be configured as an input transistor instead of an NMOS transistor, and a complementary NMOS transistor may be arranged in series with the input transistor to prevent penetration.

### OTHER MODIFIED EMBODIMENTS

In the above embodiment, the power supply voltage VDD is connected to the terminal T3 and the terminal T4 is grounded, but the present invention is not limited thereto, and different voltages may be applied between the terminals T3 and T4. In the example of the embodiment, the voltage of the terminal T3 is set to a voltage higher than the voltage of the terminal T4.

In the above embodiment, Q1 is the NMOS transistor, but the present invention is not limited thereto, and may be another switch element that is turned on when the input voltage has the high level and turned off at the low level.

In the above embodiment, Q2 is the PMOS transistor, but the present invention is not limited thereto, and may be another switch element that is turned off when the input voltage has the high level and turned on at the low level.

### INDUSTRIAL APPLICABILITY

As mentioned in detail above, according to the inverter circuit of one aspect of the present invention, it is possible to provide the inverter circuit having a predetermined threshold without any additional step of separating the back gate potential from the substrate in manufacturing and without concern of latch-up. In particular, the inverted threshold voltage of the inverter circuit that outputs the binary signal can be suppressed from varying with manufacturing variation, temperature, power supply voltage, and the like.

### REFERENCE SIGNS LIST

10 Load element
11 to 24 Constant current source
31, and 32 Current mirror circuit
F1 to F3 Trimming fuse
Q1 to Q22 MOS transistor
R1, and R2 Resistor
T1 to T4 Terminal

1. An inverter circuit comprising a series circuit including a first switch element and a load element connected in series between two voltages different from each other, the inverter circuit inverting an input voltage inputted to an input terminal by the first switch element, and outputting an inverted output voltage from an output terminal, the inverter circuit comprising:
a current source connected with the first switch element or the load element, the current source having been configured to adjust an inverted threshold voltage of the inverter circuit by adjusting a current flowing through the first switch element.

2. The inverter circuit as claimed in claim 1,
wherein the current source adjusts a current flowing through the first switch element by allowing a predetermined adjustment current to flow into or flow out of the first switch element.

3. The inverter circuit as claimed in claim 1,
wherein the load element is a resistor or a constant current source.

4. The inverter circuit as claimed in claim 1, further comprising a series circuit connected in parallel to the load element, the series circuit including at least one of a constant current source and a trimming fuse.

5. The inverter circuit as claimed in claim 1,
wherein the first switch element is an N-channel MOS transistor or a P-channel MOS transistor.

6. The inverter circuit as claimed in claim 1,
wherein the first switch element is an N-channel MOS transistor, and
wherein the series circuit further comprises a second switch element that is a P-channel MOS transistor connected in series to a series circuit of the first switch element and the load element.

7. The inverter circuit as claimed in claim 1,
wherein the current source comprises a current mirror circuit including two semiconductor elements, the current mirror circuit allowing an adjustment current corresponding to a current that changes depending on any of the two voltages different from each other to flow into or flow out of the first switch element.

8. The inverter circuit as claimed in claim 1,
wherein the current source comprises a current mirror circuit including two semiconductor elements, the current mirror circuit allowing an adjustment current corresponding to a leakage current generated by a transistor at a high temperature higher than a predetermined normal temperature to flow into or flow out of the first switch element.

9. The inverter circuit as claimed in claim 2, wherein the first switch element is an N-channel MOS transistor or a P-channel MOS transistor.

10. The inverter circuit as claimed in claim 2,
wherein the first switch element is an N-channel MOS transistor, and
wherein the series circuit further comprises a second switch element that is a P-channel MOS transistor connected in series to a series circuit of the first switch element and the load element.

11. The inverter circuit as claimed in claim 3, wherein the first switch element is an N-channel MOS transistor or a P-channel MOS transistor.

12. The inverter circuit as claimed in claim 3,
wherein the first switch element is an N-channel MOS transistor, and
wherein the series circuit further comprises a second switch element that is a P-channel MOS transistor connected in series to a series circuit of the first switch element and the load element.
